(19) United States
(12) Patent Application Publication
(10) Pub. No.: US 2023/0076065 A1
(43) Pub. Date: Mar. 9, 2023

(54) COMPOSITION FOR THE SELECTIVE ETCHING OF SILICON

(71) Applicant: ENF TECHNOLOGY CO., LTD., Gyeonggi-do (KR)

(72) Inventors: Gi Young KIM, Gyeonggi-do (KR); Tae Ho KIM, Gyeonggi-do (KR); Jeong Sik OH, Gyeonggi-do (KR); Myung Ho LEE, Gyeonggi-do (KR); Myung Geun SONG, Gyeonggi-do (KR)

(21) Appl. No.: 17/894,516

(22) Filed: Aug. 24, 2022

(30) Foreign Application Priority Data
Aug. 27, 2021 (KR) 10-2021-0114002

(51) Int. Cl. C09K 13/08

(52) U.S. Cl. CPC C09K 13/08

(57) ABSTRACT

The present invention relates to a composition for selectively etching silicon on a surface on which a metal film and silicon (Si) are exposed.

According to the present invention, it is possible to improve etch selectivity of silicon on the semiconductor surface on which the metal film and silicon are exposed.

### CROSS REFERENCE TO RELATED APPLICATIONS

This application claims the benefits of priority to Korean Patent Application No. 10-2021-0114002, filed Aug. 27, 2021, incorporated herein by reference.

### TECHNICAL FIELD

The present invention relates to an acidic composition for selectively etching silicon on a surface on which a metal film and silicon (Si) are exposed.

### BACKGROUND ART

Tungsten (W) is used as a representative plug metal in the semiconductor field.

Meanwhile, an acidic etchant of silicon comprises etching species such as hydrofluoric acid and oxidizing species such as nitric acid and sulfuric acid, for example.

The acidic etchant has a problem in that the defect rate increases because of the low selectivity of silicon with respect to the tungsten film in the silicon bulk etching of the semiconductor manufacturing process. In particular, as a metal such as tungsten is etched non-selectively, a detect may occur in a subsequent process such as the exposed lower pattern and a short circuit. This problem of the acidic etchant is a limiting factor in the application of the acidic etchant in processes such as semiconductor packaging and Through Silicon Via (TSV).

Therefore, it is necessary to study a composition that has a very low etch rate of the metal film and can selectively etch only silicon.

### DETAILED DESCRIPTION OF THE INVENTION

### Technical Problem

It is an object of the present invention to provide a composition having the improved etch selectivity of silicon to a metal film.

### Solution to Problem

In order to solve the above problems, the present invention provides a composition for selective etching of silicon, comprising:

a fluorine compound;

sulfuric acid;

nitrosylsulfuric acid;

nitric acid; and

an organic amine compound.

According to one embodiment, the fluorine compound may comprise one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

According to one embodiment, the organic amine compound may comprise one or more of polyethyleneimine, octylamine, triazole, polypropyleneimine, pentaethylenehexamine, N,N′-bis(2-aminoethyl)-1,3-propanediamine, N-(2-aminoethyl)-1,3-propanediamine, N-(3-aminopropyl)-1,3-propanediamine, spermine, spermidine, 1,4-bis(3-aminopropyl)piperazine, 1-(2-aminoethyl)piperazine, tris(2-aminoethyl)amine, branched or dendritic polyamidoamine, dendritic poly(propyleneimine) (DAB-am-16), poly(L-lysine) and chitosan.

According to one embodiment, the organic amine compound may have a molecular weight Mw of 300 to 20,000.

According to one embodiment of the present invention, the etch rate of silicon may be 2000 Å/min or more, and the etch selectivity of silicon to the metal film may be 50 or more.

According to other embodiment of the present invention, there is provided a method for preparing a composition for selective etching of silicon, comprising mixing:

0.5 to 15% by weight of a fluorine compound;

0.5 to 95% by weight of sulfuric acid;

0.1 to 20% by weight of nitrosylsulfuric acid;

0.1 to 3% by weight of nitric acid; and

0.001 to 10% by weight of an organic amine compound.

The specific details of other embodiments according to the present invention are included in the detailed description below.

### Effect of the Invention

According to the present invention, it is possible to improve etch selectivity of silicon on the semiconductor surface on which a metal film and silicon are exposed.

### BEST MODE FOR CARRYING OUT THE INVENTION

The present invention may have various modification and various embodiments, and specific embodiments will be illustrated in the drawings and described in detail. However, it is not intended to limit the present invention to specific embodiments, and should be understood to include all modifications, equivalents, and substitutes included in the spirit and scope of the present invention. In describing the present invention, if it is determined that a detailed description of a related known technology may obscure the gist of the present invention, the detailed description thereof will be omitted.

As used herein, unless otherwise specified, the expression “to” in relation to a number is used as an expression including the corresponding numerical value. Specifically, for example, the expression “1 to 2” is meant to include all numbers between 1 and 2 as well as 1 and 2.

In a semiconductor, silicon is oxidized to a silicon oxide film by oxidizing species generated from an oxidizing agent and an auxiliary oxidizing agent. The oxidized silicon oxide film is etched by contact with an etchant. When etching silicon, it is necessary to consider the selective etching amount of silicon to the metal film in order to minimize defects in the lower pattern and wiring short circuit.

In the present invention, it is intended to improve the selective etching effect of silicon to the metal film by providing a specific combination of additives.

Hereinafter, the composition for the selective etching of silicon according to embodiments of the present invention will be described in more detail.

Specifically, the present invention provides a composition for selective etching of silicon, comprising:

a fluorine compound;

sulfuric acid;

nitrosylsulfuric acid;

nitric acid; and

an organic amine compound.

The fluorine compound, which is a compound that dissociates to generate F⁻ or HF²⁻ having strong affinity with silicon, serves to etch the silicon oxide film. The fluorine compound may comprise one or more of hydrofluoric acid (HF), ammonium bifluoride (ABF; NH₄HF₂), sodium fluoride (NaF), potassium fluoride (KF), aluminum fluoride (AlF₃), fluoroboric acid (HBF₄), ammonium fluoride (NH₄F), sodium bifluoride (NaHF₂), potassium bifluoride (KHF₂) and ammonium tetrafluoroborate (NH₄BF₄). Specifically, it may comprise one or more of hydrofluoric acid, ammonium fluoride, and ammonium bifluoride, for example.

The content of the fluorine compound may be from 0.5 to 15% by weight, for example 1% by weight or more, 2% by weight or more, 3% by weight or more, and for example 10% by weight or less, 5% by weight or less. Within this content range, it is suitable for etching the silicon film with respect to the metal film.

The sulfuric acid may serve to oxidize silicon. The content of sulfuric acid may be from 0.5 to 95% by weight, for example 50% by weight or more, 60% by weight or more, 70% by weight or more, 80% by weight or more, and for example 95% by weight or less, 90% by weight or less.

Nitrosylsulfuric acid serves as a catalyst for silicon oxidation. The content of nitrosylsulfuric acid may be from 0.1 to 20% by weight, for example 0.5% by weight or more, 1% by weight or more, 2% by weight or more, and for example 15% by weight or less, 10% by weight or less, 5% by weight or less.

The present invention can effectively oxidize silicon by including both of sulfuric acid and nitrosylsulfuric acid. In particular, by including nitrosylsulfuric acid, it is possible to maintain a high concentration of oxidizing species in the etchant, thereby helping the oxidation of silicon.

The nitric acid serves as a catalyst for silicon oxidation and generates oxidizing species. The content of nitric acid may be from 0.1 to 3% by weight, for example 0.3% by weight or more, and for example 2% by weight or less, 1% by weight or less.

The organic amine compound may control the etch selectivity of silicon to the metal film. The organic amine compound may comprise a cationic additive, for example it may comprise one or more of polyethyleneimine (PEI), octylamine, triazole, poly(propyleneimine) (PPI), pentaethylene hexamine, N,N′-bis(2-aminoethyl)-1,3-propanediamine, N-(2-aminoethyl)-1,3-propanediamine, N-(3-aminopropyl)-1,3-propanediamine, spermine, spermidine, 1,4-bis(3-aminopropyl)piperazine, 1-(2-aminoethyl)piperazine, tris(2-aminoethyl)amine, branched or dendritic polyamidoamine (PAMAM), dendritic poly(propyleneimine) (DAB-am-16), poly(L-lysine) (PLL) and chitosan, specifically, for example, it may comprise one or more of polyethyleneimine, polypropyleneamine, octylamine, 1,2,4-triazole, and 1,2,3-triazole.

According to one embodiment, when the organic amine compound is polyethyleneimine, it may have a molecular weight of Mw 300 to 20,000, for example, Mw 400 or more, Mw 500 or more, or Mw 600 or more, and, for example, Mw 15,000 or less, Mw 12,000 or less, Mw 10,000 or less.

In addition, the content of the organic amine compound may be from 0.001 to 10% by weight, for example, 0.005% by weight or more, 0.01% by weight or more, 0.03% by weight or more, and for example, 5% by weight or less, 3% by weight or less, 1% by weight or less.

The present invention can improve the selective etching amount of silicon to the metal film due to the inclusion of the organic amine compound. In particular, the organic amine compound can physically adsorb to the metal surface, thereby reducing the oxidation rate of the metal. As a result, it is possible to effectively improve the etch selectivity of silicon to the metal film by lowering the etch rate of the metal film.

According to one embodiment, when treating the substrate in which the metal film and silicon are simultaneously exposed on the surface according to the present invention, the etch rate of silicon may be 2000 Å/min or more, for example 2500 Å/min or more, 3000 Å/min or more, and for example, 10000 Å/min or less, 5000 Å/min or less.

In addition, the etching selectivity Si/W of silicon (Si) to the tungsten (W) film may be for example 50 or more, 100 or more, and for example 1000 or less, 600 or less, 500 or less.

According to one embodiment, the metal film may comprise one or more of tungsten (W), titanium nitride (TiN), titanium (Ti), gold (Au), molybdenum (Mo), nickel (Ni), palladium (Pd), and platinum (Pt), specifically, for example, tungsten.

According to one embodiment, the amount of water such that the total weight of the composition is 100% by weight may be included. The water to be used is not particularly limited, but deionized water may be used. Preferably, deionized water having a specific resistance value of 18 MΩ/cm or more which indicates the degree of removal of ions in water may be used.

According to one embodiment, the composition of the present invention may further comprise any additives used in a conventional etchant composition in order to improve etching performance. For example, it may further comprise one or more selected from the group consisting of a stabilizer, a surfactant, a chelating agent, an antioxidant, a corrosion inhibitor, and a mixture thereof.

The stabilizer may be an etching stabilizer and may be added in order to suppress the generation of side reactions or byproducts that may be accompanied by unnecessary reactions of the etchant composition or the object to be etched.

The surfactant may be additionally added for the purpose of improving wettability of the etchant composition, improving foam properties of the additive, and increasing solubility of other organic additives. The surfactant may be 1 or 2 or more selected from nonionic surfactants, anionic surfactants, cationic surfactants, and amphoteric surfactants, and may be added in an amount of 0.0005 to 5% by weight based on the total weight of the composition, preferably 0.001 to 2% by weight based on the total weight of the composition. When the content of the surfactant is less than 0.0005% by weight based on the total weight of the composition, no effect can be expected, and when the content of the surfactant exceeds 5% by weight, solubility problems may occur, or process problems may occur due to excessive foaming.

The chelating agent may be additionally added for the purpose of increasing the solubility of metal impurities of the etchant composition or forming a uniform etched surface. The chelating agent may be added in an amount of 0.1 to 5% by weight based on the total weight of the composition, and may preferably be an organic acid having both of a carboxyl group and a hydroxyl group.

The antioxidant and the corrosion inhibitor may be added in order to protect metals or metallic compounds used as materials for semiconductor devices. The antioxidant and the corrosion inhibitor may be used without limitation as long as they are commonly used in the art. For example, it may include, but not limited to, an azole-based compound, and may be added in an amount of 0.01 to 10% by weight based on the total weight of the composition.

The etching method using the etching composition of the present invention may be performed according to a conventional method, and is not particularly limited.

Hereinafter, embodiments of the present invention will be described in detail so that those of ordinary skill in the art can easily carry out the present invention. However, the present invention may be embodied in several different forms and is not limited to the embodiments described herein.

### Example and Comparative Example

A composition for selective etching of silicon was prepared with the composition shown in Table 1. Each composition comprises the amount of water such that the total weight of the composition is 100% by weight.

TABLE 1

| | Content (wt %) | | | | | |
|---|---|---|---|---|---|---|
| | | | Nitroxyl- | | | |
| | | | sulfuric | | | |
| | | Sulfuric | acid | Nitric | | Additive |
| | ABF | acid | (NOHSO₄) | acid | Additive | type |
| Comparative | 3.8 | 88.9 | 3.0 | 0.5 | | |
| Example 1 | | | | | | |
| Comparative | 3.8 | 89.5 | 3.0 | | | |
| Example 2 | | | | | | |
| Comparative | 3.8 | 90.7 | 0.5 | 0.5 | | |
| Example 3 | | | | | | |
| Comparative | 0.8 | 91.2 | 3.0 | 0.5 | | |
| Example 4 | | | | | | |
| Example 1 | 3.8 | 88.6 | 3.0 | 0.5 | 0.05 | PEI-600 |
| Example 2 | 3.8 | 88.6 | 3.0 | 0.5 | 0.1 | PEI-600 |
| Example 3 | 3.8 | 88.6 | 3.0 | 0.5 | 0.2 | PEI-600 |
| Example 4 | 3.8 | 88.6 | 3.0 | 0.5 | 0.05 | PEI-10000 |
| Example 5 | 3.8 | 88.6 | 3.0 | 0.5 | 0.1 | PEI-10000 |
| Example 6 | 3.8 | 88.6 | 3.0 | 0.5 | 0.1 | Octylamine |
| Example 7 | 3.8 | 88.6 | 3.0 | 0.5 | 0.2 | Octylamine |
| Example 8 | 3.8 | 88.6 | 3.0 | 0.5 | 0.1 | 1,2,4-triazole |
| Example 9 | 3.8 | 88.6 | 3.0 | 0.5 | 0.3 | 1,2,4-triazole |

### Experimental Example 1: Evaluation of Etch Rate

In order to determine the etch rate for each composition, the substrate to be evaluated having both tungsten (W) and silicon exposed on the surface was cut to 20×20 mm, and the thickness and weight of each substrate were measured. The etchant composition according to each of Examples and Comparative Examples was introduced into a thermostat maintained at 25° C. and the substrate to be evaluated was immersed for 15 minutes to carry out the etching process. After the etching was completed, the substrate was washed with ultrapure water and then the remaining etchant composition and moisture were completely dried using a drying device. Then, the weight of the dried substrate was measured, the weight change before and after evaluation was calculated, and the etch rate was measured using Equation 1 below.

(Initial substrate thickness×weight reduction rate)/Processing time=Etch rate [Equation 1]

The results are shown in Table 2.

TABLE 2

| | Etch rate (um/min) | | Selectivity |
|---|---|---|---|
| | Si | W | Si/W |
| Comparative | 4618 | 381 | 12 |
| Example 1 | | | |
| Comparative | 1918 | 118 | 16 |
| Example 2 | | | |
| Comparative | 0 | 217 | 0 |
| Example 3 | | | |
| Comparative | 0 | 161 | 0 |
| Example 4 | | | |
| Example 1 | 3965 | 34 | 118 |
| Example 2 | 3886 | 27 | 144 |
| Example 3 | 3719 | 17 | 225 |
| Example 4 | 4128 | 36 | 115 |
| Example 5 | 4039 | 26 | 155 |
| Example 6 | 3759 | 36 | 104 |
| Example 7 | 3648 | 35 | 106 |
| Example 8 | 3751 | 37 | 101 |
| Example 9 | 3652 | 33 | 111 |

As shown in Table 2, in the case of Comparative Examples, it was confirmed that the etch selectivity (Si/W) of silicon to tungsten was as low as 20 or less. In particular, in Comparative Examples 3 and 4, silicon was hardly etched.

On the other hand, in all of Examples, it is confirmed that the etch rate of silicon is 3500 Å/min or more and the Si/W is excellent as 100 or more.

Therefore, the etchant composition according to the present invention improves the etch selectivity of silicon to the metal film effectively by lowing the etch rate of the metal film.

As described above, the specific parts of the present invention have been described in detail, and for those of ordinary skill in the art to which the present invention pertains, it is clear that these specific techniques are only preferred embodiments and the scope of the present invention is not limited thereto. Those of ordinary skill in the art to which the present invention pertains will be able to make various applications and modifications within the scope of the present invention based on the above contents. Accordingly, the substantial scope of the present invention will be defined by the appended claims and their equivalents.

What is claimed is:

1. A composition for selective etching of silicon, comprising:
a fluorine compound;
sulfuric acid;
nitrosylsulfuric acid;
nitric acid; and
an organic amine compound.

2. The composition for selective etching of silicon according to claim 1, wherein the fluorine compound comprises one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

3. The composition for selective etching of silicon according to claim 1, wherein the organic amine compound comprises one or more of polyethyleneimine, octylamine, triazole, polypropyleneimine, pentaethylenehexamine, N,N′-bis(2-aminoethyl)-1,3-propanediamine, N-(2-aminoethyl)-1,3-propanediamine, N-(3-aminopropyl)-1,3-propanediamine, spermine, spermidine, 1,4-bis(3-aminopropyl)piperazine, 1-(2-aminoethyl)piperazine, tris(2-aminoethyl)amine, branched or dendritic polyamidoamine, dendritic poly(propyleneimine) (DAB-am-16), poly(L-lysine) and chitosan.

4. The composition for selective etching of silicon according to claim 1, wherein the organic amine compound has a molecular weight Mw of 300 to 20,000.

5. The composition for selective etching of silicon according to claim 1, wherein the etch rate of silicon is 2000 Å/min or more, and the etch selectivity of silicon to a metal film is 50 or more.

6. A method for preparing a composition for selective etching of silicon, comprising mixing:
0.5 to 15% by weight of a fluorine compound;
0.5 to 95% by weight of sulfuric acid;
0.1 to 20% by weight of nitrosylsulfuric acid;
0.1 to 3% by weight of nitric acid; and
0.001 to 10% by weight of an organic amine compound.
